(19) United States
(12) Patent Application Publication
(10) Pub. No.: US 2025/0089274 A1
(43) Pub. Date: Mar. 13, 2025

(54) SEMICONDUCTOR DEVICE

(71) Applicant: SK hynix Inc., Gyeonggi-do (KR)

(72) Inventors: Hyeong Yeol PARK, Gyeonggi-do (KR); Hye Min IM, Gyeonggi-do (KR)

(21) Appl. No.: 18/533,179

(22) Filed: Dec. 8, 2023

(30) Foreign Application Priority Data
Sep. 13, 2023 (KR) 10-2023-0121589

(51) Int. Cl. H01F 17/00; H01L 23/522

(52) U.S. Cl. CPC H10D 1/20; H01F 17/0013; H01L 23/5227; H01F 2017/0073

(57) ABSTRACT

In an embodiment, a semiconductor device may include a T-coil transferring a signal from the outside to an internal circuit, a plurality of power lines transferring power from the outside to the internal circuit and disposed below the T-coil and at least one capacitor connected between the plurality of power lines.

### CROSS-REFERENCE TO RELATED APPLICATION

This application claims priority under 35 U.S.C. § 119 to Korean Patent Application No. 10-2023-0121589 filed on Sep. 13, 2023, which is incorporated herein by reference in its entirety.

### BACKGROUND

### 1. Technical Field

Embodiments of the present disclosure relate to a semiconductor integrated circuit, and more particularly, to a semiconductor device.

### 2. Related Art

Recently, in accordance with miniaturization, low power consumption, performance improvement, diversification, and the like, of electronic devices, semiconductor devices capable of storing information in various electronic devices such as computers and portable communication devices have been demanded. Accordingly, the semiconductor devices have also been studied in order to achieve miniaturization, low power consumption, and performance improvement.

In particular, in order to achieve the performance improvement of the semiconductor devices, technology for increasing transmission and reception speeds of signals has been continuously developed.

### SUMMARY

In an embodiment, a semiconductor device may include: a T-coil transferring a signal from the outside to an internal circuit; a plurality of power lines transferring power from the outside to the internal circuit and disposed below the T-coil; and at least one capacitor connected between the plurality of power lines.

In an embodiment, a semiconductor device may include: a T-coil including an inductor having a spiral shape; at least one capacitor including a dielectric layer patterned into a plurality of rectangular shapes with a longest side perpendicular to an extension direction of the inductor and located below the T-coil; and a first power line and a second power line that are electrically connected to the at least one capacitor.

### BRIEF DESCRIPTION OF THE DRAWINGS

FIGS. 1 and 2 are diagrams for briefly describing a semiconductor device in accordance with an embodiment.

FIG. 3 is a cross-sectional view for describing the structure of a semiconductor device in accordance with an embodiment.

FIG. 4 is a plan view for describing a T-coil of a semiconductor device in accordance with an embodiment.

FIGS. 5A and 5B are plan views for describing a T-coil and a capacitor of a semiconductor device in accordance with an embodiment.

FIGS. 6A and 6B are plan views for describing a T-coil and a capacitor of a semiconductor device in accordance with another embodiment.

FIGS. 7A to 7C are plan views for describing power lines in accordance with an embodiment.

FIGS. 8A, 8B, and 9 are plan views for describing a semiconductor device in accordance with still another embodiment.

### DETAILED DESCRIPTION

Various embodiments are directed to a semiconductor device capable of transmitting and receiving signals at high speed and stabilizing power.

It is possible to stabilize power of a semiconductor device while transmitting and receiving signals between the outside of the semiconductor device and the inside of the semiconductor device at high speed.

Hereafter, embodiments in accordance with the technical spirit of the present disclosure will be described with reference to the accompanying drawings.

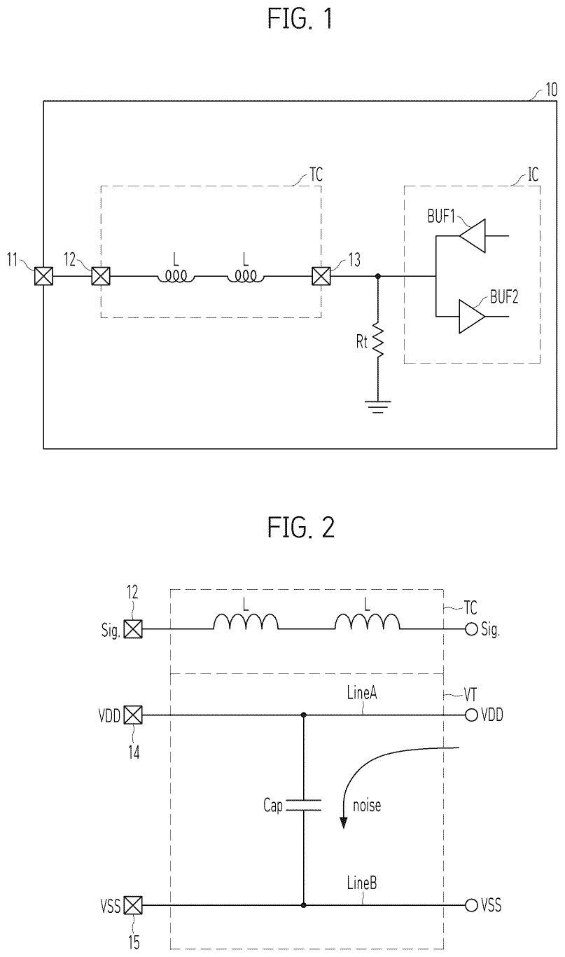

Referring to FIG. 1, the semiconductor device 10 may include a T-coil TC and an internal circuit IC. The semiconductor device 10 may further include a termination resistor Rt.

The semiconductor device 10 may be configured so that a signal input from the outside is transferred to the internal circuit IC through the T-coil TC. For example, the semiconductor device 10 may be configured so that the signal input from the outside of the semiconductor device 10 is transferred to the T-coil TC through a pin 11. In this case, the pin 11 and a first terminal 12 of the T-coil TC may be electrically connected to each other. In addition, the semiconductor device 10 may be configured so that the signal input from the first terminal 12 is transferred to the internal circuit IC through the T-coil TC. In this case, a second terminal 13 of the T-coil TC may be electrically connected to the internal circuit IC. Additionally, the termination resistor Rt may be connected between the second terminal 13 and the internal circuit IC. Here, a process in which the signal is input from the outside of the semiconductor device 10 and transferred to the internal circuit IC through the T-coil TC is described, but a process in which a signal output from the internal circuit IC is transferred to the pin 11 through the T-coil TC may also be accomplished through the T-coil TC. Therefore, describing one of reception and transmission of a signal may have the same meaning as describing signal transmission and reception between the pin 11 and the internal circuit IC.

The T-coil TC may include at least one inductor L. At least one inductor L may be electrically connected to the first and second terminals 12 and 13. Accordingly, at least one inductor L may be located between the pin 11 and the internal circuit IC. Accordingly, at least one inductor L may be included in a signal path between the pin 11 and the internal circuit IC. Accordingly, at least one inductor L may reduce capacitance of the signal path. When the capacitance of the signal path is reduced, a signal delay between the pin 11 and the internal circuit IC may be reduced. Therefore, the T-coil TC enables the signal to be transmitted and received at high speed between the pin 11 and the internal circuit IC.

The internal circuit IC may include a plurality of buffers BUF1 and BUF2. For example, the internal circuit IC may include a transmitting buffer BUF1 and a receiving buffer BUF2. The internal circuit IC may further include circuits performing a set operation based on a signal received from the outside in addition to the plurality of buffers BUF1 and BUF2.

Referring to FIG. 2, a power transfer circuit VT may be formed below the T-coil TC transferring a signal Sig.

The power transfer circuit VT may include a plurality of power lines LineA and LineB and at least one capacitor Cap. For example, the plurality of power lines LineA and LineB may include a first power line LineA and a second power line LineB. Here, the first power line LineA may be a line transmitting an external voltage VDD. Meanwhile, the second power line LineB may be a line transmitting a ground voltage VSS. The first and second power lines LineA and LineB may be connected to third and fourth terminals 14 and 15, respectively, to be electrically connected to respective pins connected to the outside. At least one capacitor Cap may be located between the first power line LineA and the second power line LineB. One end of the capacitor Cap may be electrically connected to the first power line LineA, and the other end of the capacitor Cap may be electrically connected to the second power line LineB. Here, the capacitor Cap may reduce noise in each of the first and second power lines LineA and Line by increasing capacitance of the first and second power lines LineA and LineB. Therefore, the power transfer circuit VT may stably provide the external voltage VDD and the ground voltage VSS from the outside to the internal circuit IC.

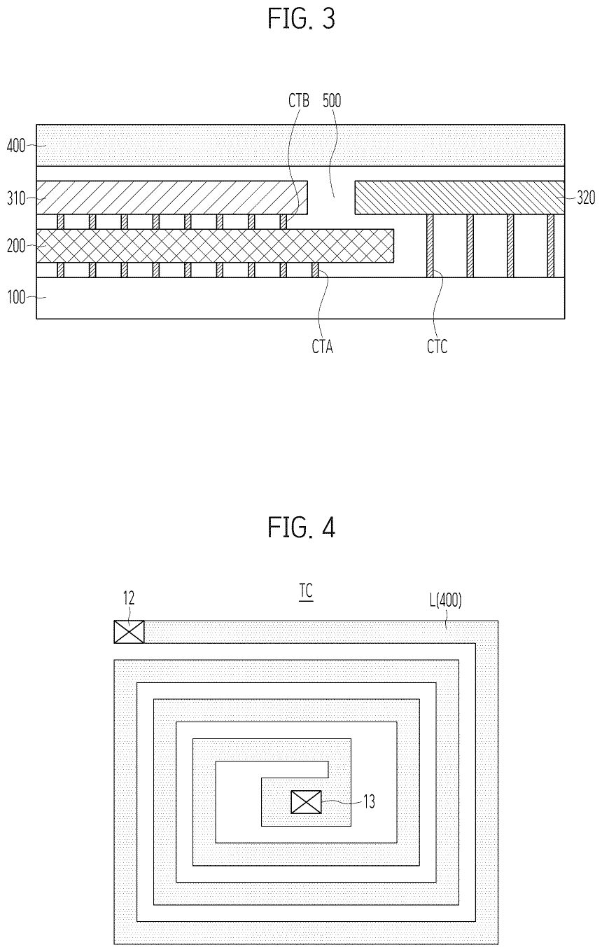

FIG. 3 is a cross-sectional view for describing the structure of a semiconductor device in accordance with an embodiment.

Referring to FIG. 3, the semiconductor device may include a plurality of conductive layers 100, 310, 320, a dielectric layer 200, an inductor 400, an insulating layer 500, and a plurality of contacts CTA, CTB, and CTC. In this case, the plurality of conductive layers 100, 310, and 320 may include a first conductive layer 100, a second conductive layer 310, and a third conductive layer 320. In addition, the plurality of contacts CTA, CTB, and CTC may include at least one first contact CTA, at least one second contact CTB, and at least one third contact CTC.

The dielectric layer 200 may be formed on the first conductive layer 100. Here, the insulating layer 500 may be formed between the first conductive layer 100 and the dielectric layer 200. In addition, at least one first contact CTA penetrating through the insulating layer 500 between the first conductive layer 100 and the dielectric layer 200 to electrically connect the first conductive layer 100 and the dielectric layer 200 to each other may be formed.

The second conductive layer 310 may be formed on the dielectric layer 200. Here, the insulating layer 500 may be formed between the dielectric layer 200 and the second conductive layer 310. In addition, at least one second contact CTB penetrating through the insulating layer 500 between the dielectric layer 200 and the second conductive layer 310 to electrically connect the dielectric layer 200 and the second conductive layer 310 to each other may be formed.

The third conductive layer 320 may be formed on the first conductive layer 100. Here, the insulating layer 500 may be formed between the first conductive layer 100 and the third conductive layer 320. In addition, at least one third contact CTC penetrating through the insulating layer 500 between the first conductive layer 100 and the third conductive layer 320 to electrically connect the first conductive layer 100 and the third conductive layer 320 to each other may be formed. A portion of the third conductive layer 320 may be formed to overlap a portion of the dielectric layer 200. In addition, the second conductive layer 310 and the third conductive layer 320 may be formed at the same layer, and the insulating layer 500 may be formed between the second conductive layer 310 and the third conductive layer 320. Accordingly, the second conductive layer 310 and the third conductive layer 320 may be electrically separated from each other.

The inductor 400 may be formed on the second conductive layer 310 and the third conductive layer 320. The insulating layer 500 may be formed between the inductor 400 and the second and third conductive layers 310 and 320. Accordingly, the inductor 400 and the second and third conductive layers 310 and 320 may be electrically separated from each other.

Here, the second conductive layer 310 may correspond to the first power line LineA illustrated in FIG. 2, and the third conductive layer 320 may correspond to the second power line LineB illustrated in FIG. 2. Therefore, the external voltage VDD may be supplied to the second conductive layer 310, and the ground voltage VSS may be supplied to the third conductive layer 320. In addition, at least one second contact CTB electrically connecting the second conductive layer 310 and the dielectric layer 200 to each other may correspond to one end of the capacitor Cap. In addition, at least one first contact CTA electrically connecting the dielectric layer 200 and the first conductive layer 100 to each other, the third conductive layer 320, and at least one third contact CTC may correspond to the other end of the capacitor Cap. Accordingly, the capacitor Cap of FIG. 2 may be composed of the second conductive layer 310, the dielectric layer 200, the first and third conductive layers 100 and 320, and at least one first to third contacts CTA, CTB, and CTC.

FIG. 4 is a plan view for describing a T-coil of a semiconductor device in accordance with an embodiment. Here, FIG. 4 may be a plan view illustrating a patterned shape of the inductor 400 illustrated in FIG. 3.

Referring to FIG. 4, the T-coil TC may include an inductor L, a first terminal 12, and a second terminal 13. For example, the inductor L may be patterned in a spiral shape. The first terminal 12 may be formed at an end of the outermost portion of the inductor L patterned in the spiral shape. In addition, the second terminal 13 may be formed at an end of the center of the inductor L patterned in the spiral shape. Here, the first terminal 12 may correspond to the first terminal 12 of FIGS. 1 and 2, and the second terminal 13 may correspond to the second terminal 13 of FIGS. 1 and 2.

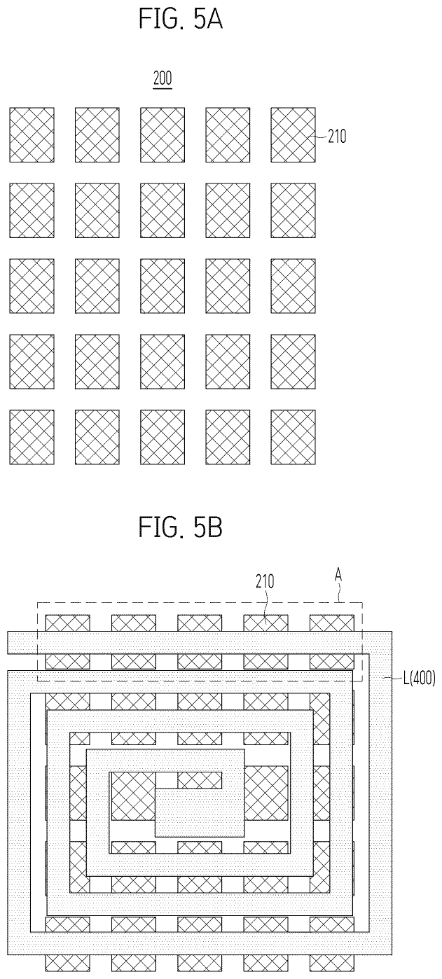

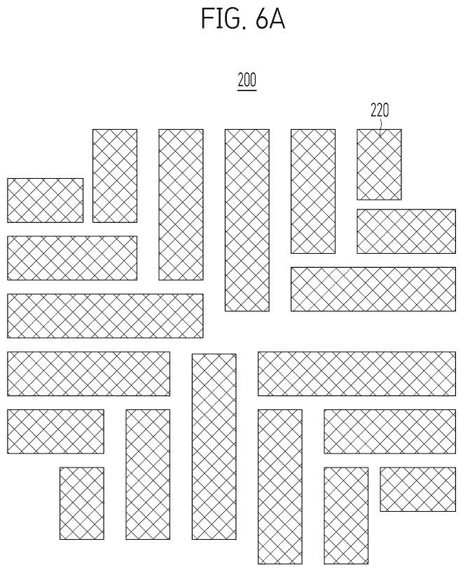

FIGS. 5A and 5B are plan views for describing a T-coil and a capacitor of a semiconductor device in accordance with an embodiment. Here, FIG. 5A may be a plan view illustrating a patterned shape of the dielectric layer 200 illustrated in FIG. 3. In addition, FIG. 5B may be a plan view illustrating only the patterned dielectric layer 200 and the patterned inductor L.

Referring to FIGS. 5A and 5B, the dielectric layer 200 may be patterned into a plurality of rectangular shapes 210 with the same size. The dielectric layer 200 may be patterned so that a direction in which the inductor L extends and a length direction of rectangles of the dielectric layers 210 having the rectangular shapes with the same size are perpendicular to each other, as illustrated in portion A of FIG. 5B. Here, a length of the rectangle may refer to a side longer than a width of the rectangle.

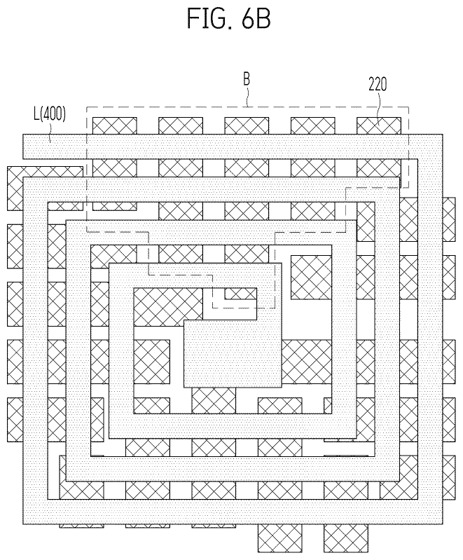

FIGS. 6A and 6B are plan views for describing a T-coil and a capacitor of a semiconductor device in accordance with another embodiment. Here, FIG. 6A may be a plan view illustrating a patterned shape of the dielectric layer 200 illustrated in FIG. 3. In addition, FIG. 6B may be a plan view illustrating only the patterned dielectric layer 200 and the patterned inductor L.

Referring to FIGS. 6A and 6B, the dielectric layer 200 may be patterned into a plurality of rectangular shapes 220 with different sizes. The dielectric layer 200 may be patterned so that a direction in which the inductor L extends and a length direction of rectangles of the dielectric layers 220 having the rectangular shapes with the different sizes are perpendicular to each other, as illustrated in portion B of FIG. 6B. Here, a length of the rectangle may refer to a side longer than a width of the rectangle.

As illustrated in FIGS. 5B and 6B, the dielectric layer 200 may be patterned so that lengths of the dielectric layers 210 and 220 having the rectangular shapes are perpendicular to the direction in which the inductor L extends, and the dielectric layer 200 perpendicular to the direction in which the inductor L extends may reduce an eddy current that may occur due to the inductor L. Accordingly, the T-coil TC may reduce loss due to the eddy current, and thus, characteristics of the T-coil TC may be improved.

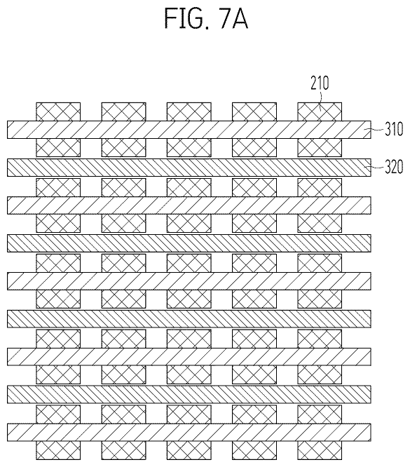

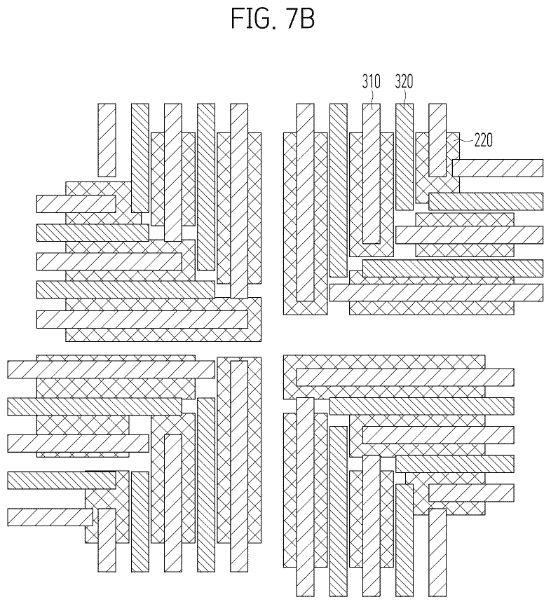

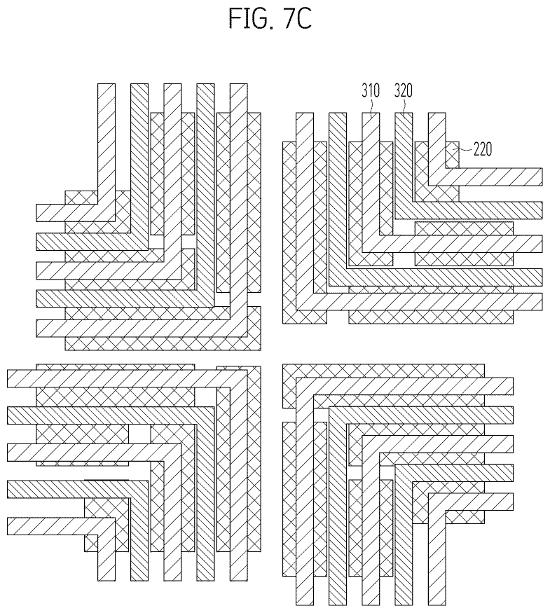

FIGS. 7A to 7C are plan views for describing power lines in accordance with an embodiment.

Referring to FIG. 7A, second conductive layers 310 located on the patterned dielectric layers 210 having the rectangular shapes with the same size may be patterned to form a first power line LineA. Third conductive layers 320 may also be patterned to form a second power line LineB. In this case, the patterned third conductive layers 320, that is, the second power line LineB, may be located between the patterned dielectric layers 210 or may partially overlap the patterned dielectric layer 210.

Referring to FIGS. 7B and 7C, second conductive layers 310 located on the patterned dielectric layers 220 having the rectangular shapes with the different sizes may be patterned to form a first power line LineA. Third conductive layers 320 may also be patterned to form a second power line LineB. In this case, the patterned third conductive layers 320, that is, the second power line LineB, may be located between the patterned dielectric layers 220 or may partially overlap the patterned dielectric layer 220.

Referring to FIGS. 7A to 7C, the first power line LineA may be patterned to be located on the patterned dielectric layers 210 and 220, and the second power line LineB may be patterned to be located between the patterned dielectric layers 210 and 220. In addition, the patterned second conductive layers 310 of FIGS. 7A to 7C may be electrically connected to each other to form the first power line LineA. In addition, the patterned third conductive layers 320 may also be electrically connected to each other to form the second power line LineB.

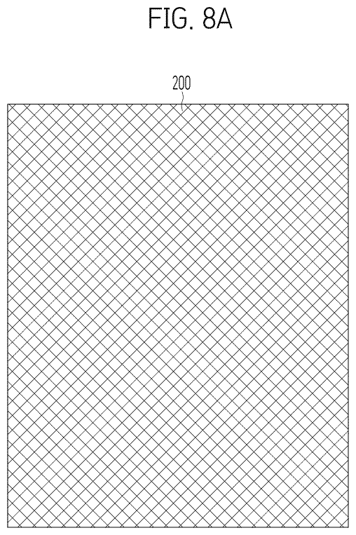

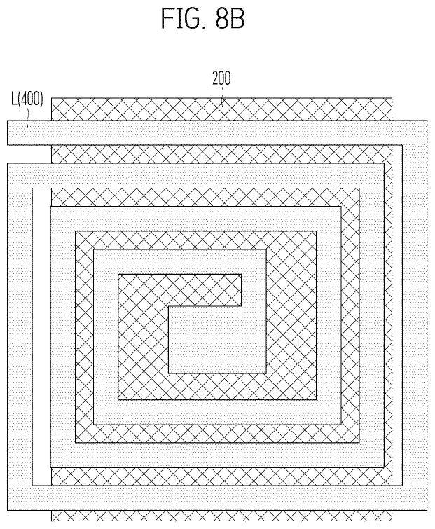

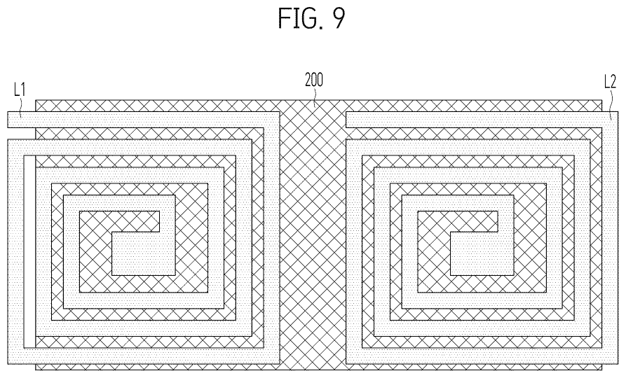

FIGS. 8A, 8B, and 9 are plan views for describing a semiconductor device in accordance with still another embodiment.

FIG. 8A may be a plan view illustrating a dielectric layer 200 that is not patterned. Referring to FIGS. 8A and 8B, the semiconductor device in accordance with still another embodiment may be implemented by forming an inductor L or 400 having a spiral shape on the dielectric layer 200 that is not patterned.

In addition, referring to FIGS. 8A and 9, the semiconductor device in accordance with still another embodiment may be implemented by forming a plurality of inductors L1 and L2 having a spiral shape on the dielectric layer 200 that is not patterned.

In the semiconductor device according to the present disclosure, it is possible to reduce the eddy current that may occur in the T-coil TC by forming the dielectric layer 200 below the T-coil TC. In addition, it is possible to further stabilize power transferred through the power lines LineA and LineB by forming the capacitor Cap including the dielectric layer 200 and connected to the power lines LineA and LineB.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a T-coil transferring a signal from the outside to an internal circuit;
a plurality of power lines transferring power from the outside to the internal circuit and disposed below the T-coil; and
at least one capacitor connected between the plurality of power lines.

2. The semiconductor device of claim 1, wherein the plurality of power lines include a first power line and a second power line,
the first power line transfers an external voltage, and
the second power line transfers a ground voltage.

3. The semiconductor device of claim 2, wherein the T-coil includes an inductor patterned in a spiral shape.

4. The semiconductor device of claim 3, wherein the at least one capacitor comprises:
a dielectric layer formed on a first conductive layer,
a second conductive layer formed on the dielectric layer,
a third conductive layer formed at the same layer as the second conductive layer.

5. The semiconductor device of claim 4, wherein the dielectric layer
is patterned into a plurality of rectangular shapes, and
is patterned so that a longest side of a rectangle is perpendicular to an extension direction of the inductor.

6. The semiconductor device of claim 4, wherein an insulating layer is formed between the first conductive layer and the dielectric layer, between the dielectric layer and the second conductive layer, and between the first conductive layer and the third conductive layer.

7. The semiconductor device of claim 6, wherein the at least one capacitor further comprises:
at least one first contact penetrating through the insulating layer between the first conductive layer and the dielectric layer to electrically connect the first conductive layer and the dielectric layer to each other;
at least one second contact penetrating through the insulating layer between the dielectric layer and the second conductive layer to electrically connect the dielectric layer and the second conductive layer to each other; and
at least one third contact penetrating through the insulating layer between the first conductive layer and the third conductive layer to electrically connect the first conductive layer and the third conductive layer to each other.

8. The semiconductor device of claim 7, wherein the second conductive layer corresponds to the first power line, and
the third conductive layer corresponds to the second power line.

9. A semiconductor device comprising:
a T-coil including an inductor having a spiral shape;
at least one capacitor including a dielectric layer patterned into a plurality of rectangular shapes with a longest side perpendicular to an extension direction of the inductor and located below the T-coil; and
a first power line and a second power line that are electrically connected to the at least one capacitor.

10. The semiconductor device of claim 9, wherein one of the first power line and the second power line is located on the dielectric layer.
